(19) United States
(12) Patent Application Publication
(10) Pub. No.: US 2008/0217700 A1
(43) Pub. Date: Sep. 11, 2008

(54) Mobility Enhanced FET Devices

(76) Inventors: Bruce B. Doris, Brewster, NY (US); Cyril Cabral, Mahopac, NY (US); Elizabeth A. Duch, Carmel, NY (US); Stephen M. Rossnagel, Pleasantville, NY (US); Michelle L. Steen, Danbury, CT (US)

Correspondence Address: INNOVATION INTERFACE, LLC, 303 TABER AVENUE, PROVIDENCE, RI, 02906, US

(21) Appl. No.: 11/684,619

(22) Filed: Mar. 11, 2007

(51) Int. Cl. H01L 29/76; H01L 21/336

(52) U.S. Cl. 257/382; 438/197; 257/E29.226; 257/E21.409

(57) ABSTRACT

NFET and PFET devices with separately stressed channel regions, and methods of their fabrication is disclosed. A FET is disclosed which includes a gate, which gate includes a metal in a first state of stress. The FET also includes a channel region hosted in a single crystal Si based material, which channel region is overlaid by the gate and is in a second state of stress. The second state of stress of the channel region is of an opposite sign than the first state of stress of the metal included in the gate. The NFET channel is usually in a tensile state of stress, while the PFET channel is usually in a compressive state of stress. The methods of fabrication include the deposition of metal layers by physical vapor deposition (PVD), in such manner that the layers are in stressed states.

### FIELD OF THE INVENTION

The present invention relates to electronic devices. In particular, it relates to FET devices in which the channel region is under tensile or compressive stress. The present invention also relates to methods for producing such structures by the incorporation of stressed metal into the gate of the devices.

### BACKGROUND OF THE INVENTION

Today's integrated circuits include a vast number of devices. Smaller devices and shrinking ground rules are the key to enhance performance and to reduce cost. As FET (Field-Effect-Transistor) devices are being scaled down, the technology becomes more complex, and changes in device structures and new fabrication methods are needed to maintain the expected performance enhancement from one generation of devices to the next. The mainstay material of microelectronics is silicon (Si), or more broadly, Si based materials. One such Si based material of importance for microelectronics is the silicon-germanium (SiGe) alloy.

There is a great difficulty in maintaining performance improvements in devices of deeply submicron generations. Therefore, methods for improving performance without scaling down have become of interest. One general approach for improving performance is to increase carrier (electron and/or hole) mobilities in FETs. A promising avenue toward better carrier mobility is to modify the semiconductor where the current conduction takes place. It has been known, and recently further studied, that tensilely or compressively stressed semiconductors have intriguing carrier properties.

For uniaxial stress, electron mobility in Si for a (100) surface orientation may increase when the channel is under tensile stress either in the longitudinal, or in the transverse direction. Longitudinal direction is defined as the direction of the current flow from source to drain, and transverse direction is defined as the direction perpendicular to the device current flow. Hole mobility on the other hand, may improve in (100) surface oriented Si for compressive channel stress in the longitudinal direction, and for tensile channel stress in the transverse direction.

In particular, improvement in the electron mobility has been achieved in a silicon (Si) channel NFET under tensile stress, as described in U.S. Pat. No. 6,649,492 B2 to J. O. Chu entitled “Strained Si Based Layer Made By UHV-CVD, and Devices Therein” incorporated herein by reference. Similarly for hole enhancement, compressively-stressed Si and SiGe have yielded high hole mobilities. Combination of tensilely and compressively stressed global SiGe regions in the same wafer is described in U.S. Pat. No. 6,963,078 to J. O. Chu “Dual Strain-State SiGe Layers for Microelectronics”, incorporated herein by reference. Techniques where stress is generated locally, essentially within the devices themselves, have been also demonstrated, as in “High speed 45 nm gate length CMOSFETs integrated into a 90 nm bulk technology incorporating strain engineering” V. Chan et al., IEDM Tech. Dig., pp. 77-80, 2003, and “Dual stress liner for high performance sub-45 nm gate length SOI CMOS manufacturing” Yang, H. S., IEDM Tech. Dig., pp. 1075-1078, 2004, both incorporated herein by reference.

Optimally, one would like to have integrated circuits such that the channel of electron conduction type devices, such as NFET, is hosted in tensilely stressed Si or SiGe, while the channel of hole conduction type devices, such as PFET, are hosted in compressively stressed Si or SiGe. However, the techniques used to date for achieving such stressed channels lacked full satisfaction, either due to their complexity, or due to their relative ineffectiveness.

### SUMMARY OF THE INVENTION

In view of the discussed difficulties, embodiments of the present invention disclose a NFET device and a PFET device with channels independently stressed from one another. The NFET channel is usually in a tensile state of stress, while the PFET channel is usually in a compressive state of stress. A field effect transistor (FET) is disclosed which includes a gate, which gate includes a metal in a first state of stress. The FET also includes a channel region hosted in a single crystal Si based material. The channel region is overlaid by the gate, and the channel region is in a second state of stress. The second state of stress of the channel region is of an opposite sign than the first state of stress of the metal included in the gate.

The invention further discloses a method for producing a FET. The method includes the deposition of a metal layer by physical vapor deposition (PVD) in such manner that the metal layer is in a first state of stress. The method further includes the incorporation of the metal layer into the gate of the FET. Consequently, the stressed metal layer imparts a second state of stress on the channel region of the FET in a way that the second state of stress is of opposite sign than the first state of stress.

### BRIEF DESCRIPTION OF THE DRAWINGS

These and other features of the present invention will become apparent from the accompanying detailed description and drawings, wherein:

FIG. 1A shows states of stress for metal layers;

FIG. 1B shows a schematic cross section of essentially completed FET transistors in an embodiment of the invention;

FIG. 2 shows a schematic cross section of a stage in the processing where a metal layer in a state of compressive stress has been deposited;

FIG. 3 shows a schematic cross section of a stage in the processing where a metal layer in a state of tensile stress has also been deposited;

FIG. 4 shows a schematic cross section of a stage in the processing where the compressive and tensile metal layers have been incorporated into gates for NFET and PFET devices;

FIG. 5 shows a schematic cross section of a stage in the processing for an alternate embodiment where voids at the gates have been prepared for metal deposition;

FIG. 6 shows a schematic cross section of a stage in the processing for an alternate embodiment as metal layers in the state of compressive and tensile stress are being processed;

FIG. 7 shows a schematic cross section of essentially completed FET transistors in an alternate embodiment of the invention; and

FIG. 8 shows a symbolic view of a processor containing at least one FET transistor with a stressed metal gate.

### DETAILED DESCRIPTION OF THE INVENTION

It is understood that Field Effect Transistor-s (FET) are well known in the electronic arts. Standard component of a FET are the source, the drain, the body in-between the source and the drain, and the gate. The gate is overlaying the body and is capable to induce a conducting channel in the body between the source and the drain. In the usual nomenclature, the channel is hosted by the body. The gate is typically separated from the body by the gate insulator. Depending whether the “on state” current in the channel is carried by electrons or holes, the FET comes as NFET or PFET. (In different nomenclature the NFET and PFET devices are often referred to as NMOS and PMOS devices.) It is also understood that frequently the NFET and PFET devices are used together in circuits, typically coupled into CMOS configurations. Manufacturing of NFET, PFET, and CMOS is very well established in the art. It is understood that there are large number of steps involved in such processing, and each step might have practically endless variations, known to those skilled in the art. In this disclosure it is understood that the whole range of known processing techniques are available for fabricating the devices, and only those process steps will be detailed that are related to the present invention. The most common material of microelectronics is silicon (Si), or more broadly Si based materials. Si based materials are various alloys of Si in the same basic technological content as Si. One such Si based material of importance for microelectronics is the silicon germanium (SiGe) alloy. The devices in the embodiments of the present disclosure are typically part of the art of single crystal Si based material device technology.

Embodiments of the present invention combine the enhanced electron mobility of NFET devices having tensile stress in their channels and the enhanced hole mobility of PFET devices having compressively stressed channels. The applied stress acts primarily in the longitudinal direction. The stress in the channels of the devices is attained by fabricating gates which include stressed metals, and the stress from the gates transfers to the channel regions. It is known, for instance, as described in U.S. Pat. No. 6,977,194 to Belyansky et al. entitled “Structure and method to improve channel mobility by gate electrode stress modification” incorporated herein by reference, that a compressive stress present in a gate electrode leads to a tensile stress in the channel of the transistor device, and conversely, a tensile stress present in a gate electrode leads to a compressive stress in the channel of the transistor device. Embodiments of this invention utilize metal films deposited using specific processing conditions that enable the metal layers to be either in a tensile state of stress or in a compressive state of stress. These film deposition techniques fit seamlessly into the known art of CMOS processing. Thus, by incorporating into the gate of NFET devices a compressively stressed metal layer, one can enhance electron mobility in the transistor. Similarly, by incorporating into the gate of PFET devices a metal layer in tensile state of stress, one can enhance hole mobility in the transistor.

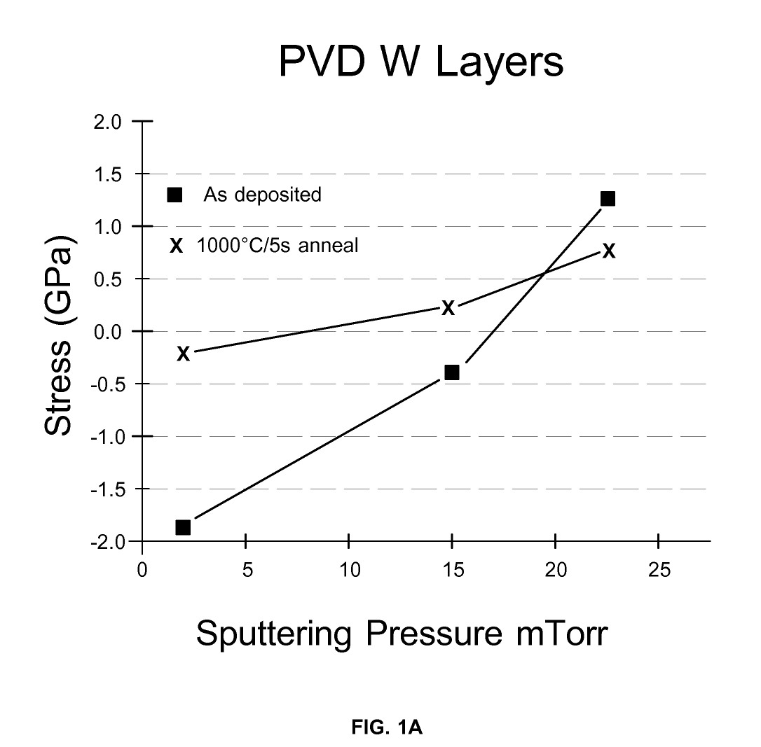

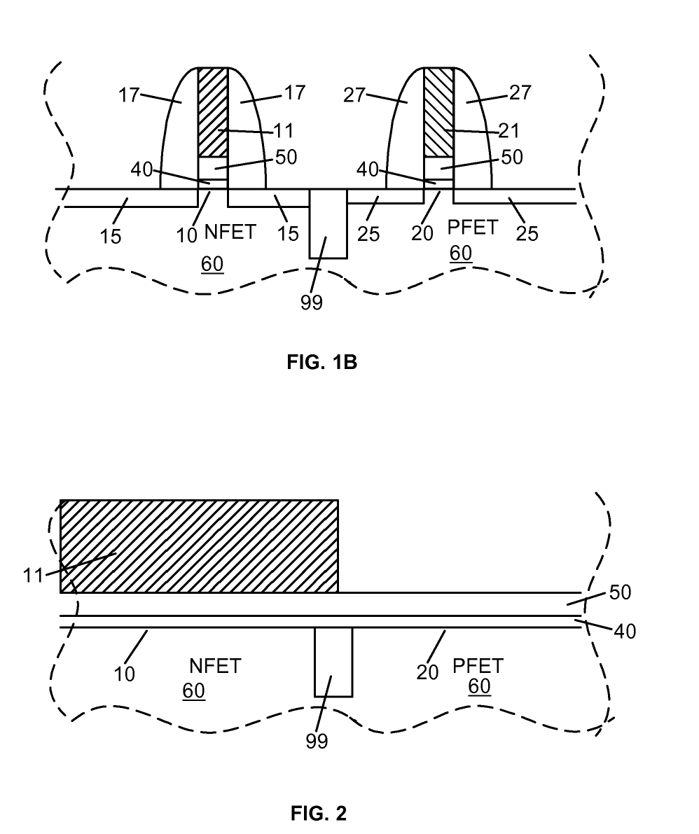

FIG. 1A shows measured levels of stress in deposited metal layers. By a properly applied procedure, typically by Physical Vapor Deposition (PVD), and more specifically by sputtering, the adjustment of parameters of the deposition leads to varying stress in the deposited metal layer. As FIG. 1A shows, the metal layer can go from a compressive state of stress to one of tensile state of stress by just changing deposition parameters, such as the sputtering pressure. The state of stress of the metal layer changes sign from compressive to tensile, or vice versa, from tensile to compressive, depending on appropriate deposition parameter selection. The Tungsten (W) layers usually were deposited at about 2.5 kW of power in about the 0.65 mTorr to 23 mTorr Ar pressure range.

The layer thickness of interest for various embodiments of the invention can vary significantly, and may be in the range of about 5 nm to 200 nm. The W layers in representative embodiments may be between about 145 nm to about 175 nm thick. It was observed that the deposited layers maintained a significant fraction of the as deposited stress values even after heat treatment, such as for instance, 1000° C. for many seconds. Such a heat budget may be encountered in device processing if the metal is deposited early in the fabrication. In representative embodiments of the present invention the metal in use is W. However, one may contemplate using other metals, the kind that often find their way into FET gates, such as Mo, Mn, Ta, TaN, TiN, WN, Ru, Cr, Ta, Nb, V, Mn, Re and their mixtures, as well.

FIG. 1B shows a schematic cross section of essentially completed FET transistors in an exemplary embodiment of the invention. The figure shows an NFET and a PFET device. The devices may be isolated from one another by some means. In FIG. 1B, without limiting other possibilities, including the lack of isolation, a shallow trench isolation 99 scheme is shown, as this may be a typical isolation available in the art. The channel region 10 of the NFET device and the channel region 20 of the PFET device are hosted in a single crystal Si based material 60. The respective gates are overlaying the channel regions. The NFET device includes a compressively stressed metal 11. This metal in an exemplary embodiment is W. The metal 11 in the gate is in a compressive state of stress, and imparts a tensile state of stress onto the NFET channel region 10. The sign of the stress is opposite in the gate metal compared to the channel region. The tensile state of stress in the NFET channel region is a sought effect, since it improves performance in electron conduction type transistors. Similarly, the PFET device includes a tensilely stressed metal 21. This metal in an exemplary embodiment is W, same as in the NMOS device. This metal 21 in the gate is in a tensile state of stress, and imparts a compressive state of stress onto the PFET channel region 20. The sign of the stress is opposite in the gate metal compared to the channel region. The longitudinal compressive state of stress in the PFET channel region is a sought effect, since it improves performance in hole conduction type transistors.

As the device is shown in FIG. 1B, there are other material layers between the stressed metal in the gate and the channel. One normally present is the gate insulator 40. From the point of view of embodiments of the present invention, practically any kind of gate insulator is acceptable. Such gate insulators known in art may be oxide, oxinitride, so called high-K materials, or others. The figure shows another layer 50 between the gate insulator 40 and the stressed metals. In representative embodiments of the invention such an intervening layer 50 may, or may not, be present. It is acceptable, and depending on a particular embodiment it may be desirable, that the stressed metal in the gate directly contacts the gate insulator. Or, there maybe an intervening layer 50 between the gate insulator and the stressed metal. Such an intervening layer 50 may be essentially of any kind of material, for instance, semiconductor, or metallic such as silicide. The inter intervening layer 50 itself may be a layered structure, composed of more than one material layer. The intervening layer 50 may serve as an etch stop layer, and may play a role in adjusting device thresholds. The intervening layer 50 in contact with the gate insulator may be polysilicon. Such a polysilicon layer may serve as a differential etch stop, and the doping in the polysilicon layer may be used for adjusting the threshold of the device. The NFET and PFET devices independently of one another may, or may not, contain such intervening layers, and the properties of an intervening layer 50 in a NFET may be different, or may be the same, as an intervening layer 50 in a PFET.

In order to exhibit a more complete device, besides the gates and the channels, FIG. 1B schematically indicates NFET source and drain 15, and sidewall spacers 17, and similarly for the PFET device, source and drain 25, and sidewall spacers 27.

For a FET, in general, without specifying PFET or NFET, a representative embodiment of the invention has a metal in a first state of stress, and the channel, which is overlaid by the gate, is in a second state of stress. The second state of stress of the channel is of opposite sign than the first state of stress of the metal in the gate. The metal in the gate is usually not a silicide, consequently contains essentially no Si. If the first state of stress is compressive then the second state of stress is tensile, and the other way around, if the first state of stress is tensile then the second state of stress is compressive.

It may be of note that the metal in the NFET gate 11 and in the PFET gate 21 is the same metal, in a typical embodiment W. The difference between the two devices is in the state of stress of the metal. The appropriate state of stress for each device was selected, and attained, through the adjustment of parameters in the PVD process during metal layer deposition.

FIGS. 2 to 4 show steps in the fabrication process of an exemplary embodiment of a gate-first fabrication process. The term “gate-first” has the customary meaning, namely, that the gate of the device is fabricated before the source and drain of the device are activated. The gate-first approach is the most common in the FET device fabrication arts. In this case the metal gates receive the thermal budget that is needed for activating the source and the drain, and a partial relaxation compared to the as-deposited stress of the metal may occur.

FIG. 2 shows a schematic cross section of a stage in the processing where a metal layer in a state of compressive stress has been deposited. Again, the display, and the discussion of steps well known in the art, such as typical masking, patterning, etching, and other similar steps, will be omitted. One defines a first location for fabricating the NFET devices and defines a second location for fabricating the PFET devices. Typically a shallow trench isolation 99 is used in separating NFET and PFET device regions. The isolation is typically followed by gate dielectric 40 processing. The gate dielectric 40 may be overlaid by a thin intervening layer 50. This intervening layer 50 may be polysilicon and may be properly doped in each of the NFET and PFET regions for threshold adjustment. Next, a compressively stressed first layer of a metal 11, typically W, is deposited, and later etched, leaving it only over the NFET regions. The future place of the channels 10 and 20 are indicated in their respective regions. The channels are usually hosted in single crystal Si based material 60, which is typically essentially pure Si, with a (100) oriented surface.

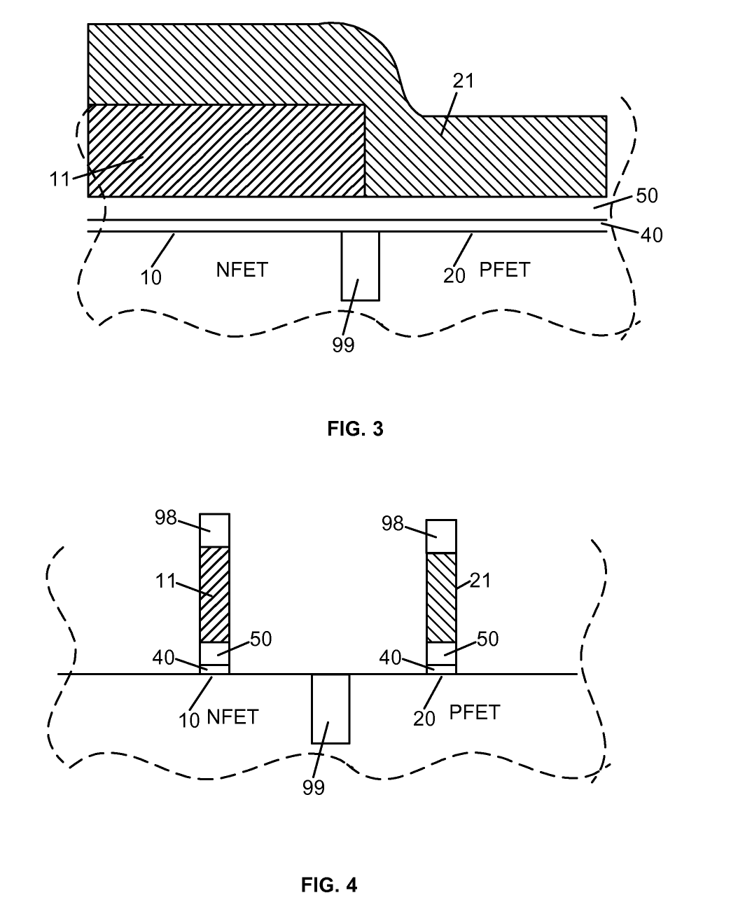

FIG. 3 shows a schematic cross section of a stage in the processing of the FET transistors where a second layer of the same metal, in the state of tensile stress, has also been deposited. In FIG. 3 the second layer of the metal in the tensile state 21, typically W, is shown before masking and etching, or maybe polishing, which steps later remove the second layer of the metal in the NFET regions.

FIG. 4 shows a schematic cross section of a stage in the processing where the compressive and tensile metal layers have been incorporated into gates for NFET and PFET devices. Incorporation into the gates in representative embodiments of the invention means that the metal layers have been patterned and etched, leaving only the gate stacks overlaying the respective NFET channel region 10 and PFET channel region 20. The stressed metal layers over the NFET and PFET devices do not have to be of the same thickness. FIG. 4 shows a stage where a masking layer 98 still covers the gate stacks. Typically the masking layers are removed in later processing. FIG. 4 shows essentially the end of the unique steps relevant for the invention in the gate-first fabrication. From here on, standard steps known in the art may complete the fabrication, reaching a typical final state, as it is shown in FIG. 1B.

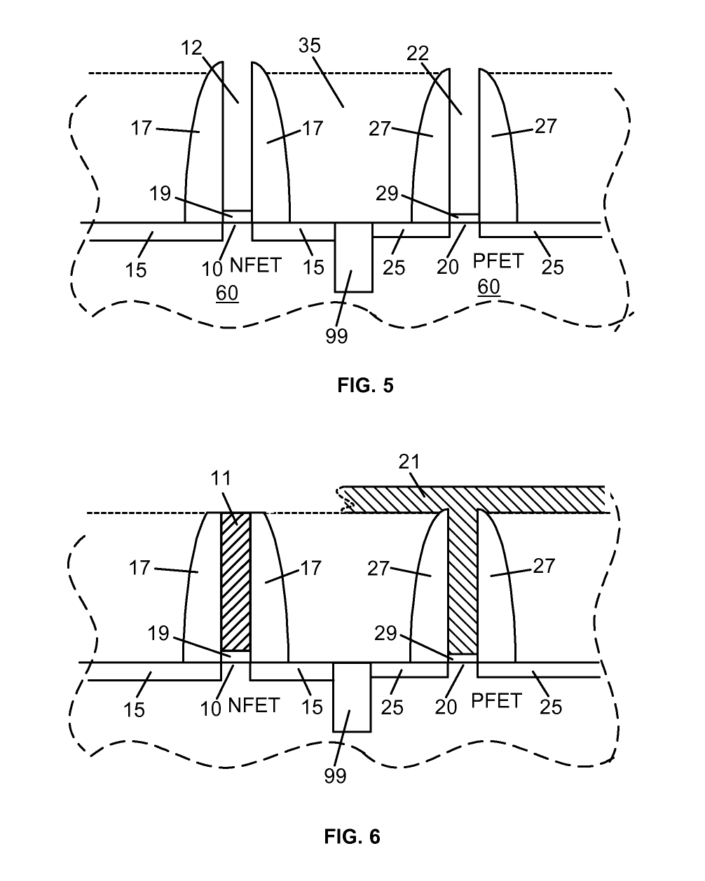

FIGS. 5 to 7 show steps in the fabrication process of an exemplary embodiment of a gate-last fabrication process. The term “gate-last” has the customary meaning, namely, that the gate of the device is fabricated after the source and drain of the device have been activated. In the gate-last case the metal gates do not receive the thermal budget that is needed for activating the source and the drain, consequently, the stress in the metal layers remains at the as-deposited level. In FET processing, typically the largest temperature budgets, meaning temperature and time exposure combinations, are reached during source/drain fabrication. Since the sources and drains have already been fabricated for the gate-last approach when the stressed metal is deposited, such high temperature fabrication steps have already been performed, and the structure will not have to be exposed to further large temperature budget treatment. From the perspective of embodiments of the present invention, exposure to a large temperature budget means a comparable heat treatment as the one used in the source/drain fabrication. Again, it is understood that the discussion of steps well known in the art, such as typical masking, patterning, etching, and other similar steps, is omitted.

FIG. 5 shows a schematic cross section of a stage in the processing of FET transistors in a gate-last embodiment, where the gate voids have been prepared for metal deposition. In such an embodiment a “dummy” gate is fabricated and the processing is carried out past the activation of the NFET source and drain 15 and the PFET source and drain 25. At this point the “dummy” gates are removed, typically by an etching procedure, leaving voids 12 and 15 in their respective places. During the removal of the “dummy” gates gate insulators, and possibly some further layers covering the channel regions may, or may not, be removed, as it is known in the art. The figures show only a NFET gate insulator 19 and a PFET gate insulator 29, but this is only for illustration purposes. In given embodiments, other intervening layers 50, such as but not limited to polysilicon, or another metal, may be present, or presently deposited over the gate insulators. The gate insulator 19 of the NFET device may be the same as the gate insulator 29 of the PFET device, or they may be different, as it is known in the art. A filler material 35 may have been deposited to better control the metal layer deposition.

FIG. 6 shows a schematic cross section of a stage in the processing for a gate-last embodiment, as metal layers in the state of compressive and tensile stress are being processed. With proper masking, a first and second layer of the metal, typically W, in the compressive state 11, and in the tensile state 21 respectively, has been deposited, and is filling the voids left by the removal of the “dummy” gates. Next, an etching, or a polishing step follows, which removes the unwanted portion of the deposited metals. In the FIG. 6, for illustration, the NFET metal has already been polished down, while over the PFET the metal may be shown in its as deposited state.

As one skilled in the art would know there may be many variations in the sequences of depositions, etchings, planarizations, and other processing steps. One typical method for the gate-last approach may be to remove the dummy gate material from on one FET first, and then fill with the first layer of metal of a first stress type then use CMP to remove metal from everywhere except from inside the hole. Next, a selective etch is used to remove dummy gate material from the second FET while keeping the stressed material in the first gate hole, and repeating the process with the second layer of metal in a second stress type.

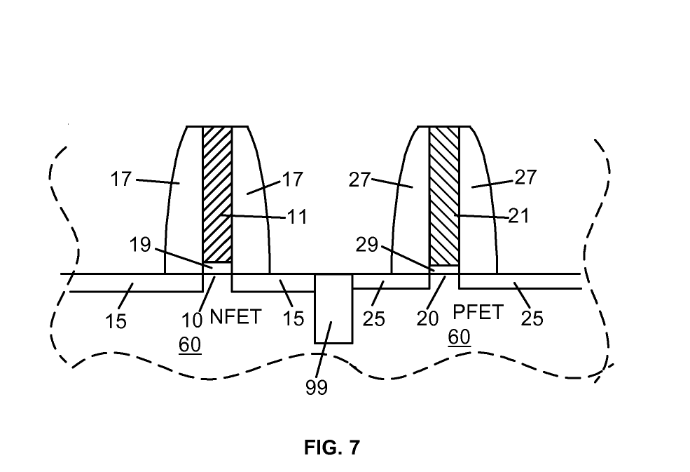

A basically completed stage of the devices is shown on FIG. 7. The essentially final structures, shown in FIGS. 1B and 7, are very similar, independently whether a gate-first, or a gate-last, processing approach was used to embody the invention.

Incorporating the metal layers 11, 21 into the gates of the FET devices in representative embodiments of the invention may involve process steps such as patterning and etching, or polishing. It does not involve significant chemical reactions, such as, for instance, silicidation. Consequently, the stressed metal layers of the invention are essentially free of Si. The composition of the metal as is incorporated in the gate stack of the completed device structure is essentially the same as it was deposited.

With the disclosed methods of fabrication the embodiment where tensile stress is applied to the channel of the NFET and compressive stress to the channel of the PFET, can be reversed, if desired. One may use compressively stressed metal layer for the PFET gate and tensilely stressed metal for the NFET gate. Such arrangements may be applied, for one, or both, kind of device, for instance to make them more equal in performance, or to achieve any desired beta ratio. This in turn may help circuit design, or help with the physical layout of devices on the chips.

It is understood that any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as “longitudinal”, “transverse”, “on”, “over” and similar ones, as used herein refer to relative direction, location, and orientation of various portions of the structures with respect to one another, and are not intended to suggest that any particular absolute orientation with respect to external objects is necessary or required.

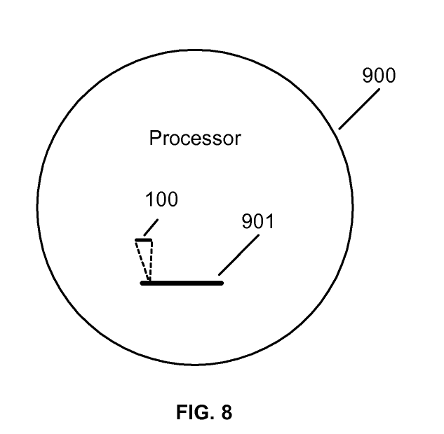

FIG. 8 shows a symbolic view of a processor containing at least one FET transistor with a stressed metal gate. Such a processor 900 has at least one chip 901, which contains at least one FET 100, which has a gate that includes a stressed metal. The processor 900 may be any processor which can benefit from the stressed metal gate device 100. Representative embodiments of processors manufactured with such stressed metal gate devices are digital processors, typically found in the central processing complex of computers; mixed digital/analog processors, typically found in communication equipment; and others.

Many modifications and variations of the present invention are possible in light of the above teachings, and could be apparent for those skilled in the art. The scope of the invention is defined by the appended claims.

We claim:

1. A field effect transistor (FET), comprising:
a gate, wherein said gate comprises a metal in a first state of stress, wherein said metal is essentially free of Si;
a channel region hosted in a single crystal Si based material, wherein said channel region is overlaid by said gate, wherein said channel region is in a second state of stress, and wherein said second state of stress is of opposite sign than said first state of stress.

2. The FET of claim 1, wherein said transistor is N-type, wherein said first state of stress is compressive stress, and said second state of stress is tensile stress.

3. The FET of claim 1, wherein said transistor is P-type, wherein said first state of stress is tensile stress, and said second state of stress is compressive stress.

4. The FET of claim 1, wherein said metal is Tungsten (W).

5. The FET of claim 1, wherein said FET further comprises a gate insulator, and wherein said metal is in direct contact with said gate insulator.

6. The FET of claim 1, wherein said FET further comprises a gate insulator and an intervening layer, wherein said intervening layer is sandwiched therebetween said metal and said gate insulator.

7. A device structure, comprising:
at least one NFET device, wherein said least one NFET device comprises a NFET gate, wherein said NFET gate comprises a metal in a compressive state of stress; and
at least one PFET device, wherein said least one PFET device comprises a PFET gate, wherein said PFET gate comprises said metal in a tensile state of stress.

8. The device structure of claim 7, wherein said metal is Tungsten (W).

9. The device structure of claim 7, wherein said least one NFET device further comprises a NFET channel region, wherein said NFET channel region is overlaid by said NFET gate, wherein said NFET channel region is in a tensile state of stress, and wherein said least one PFET device further comprises a PFET channel region, wherein said PFET channel region is overlaid by said PFET gate, wherein said PFET channel region is in a compressive state of stress.

10. The device structure of claim 7, wherein said least one NFET device and said least one PFET device each comprise a gate insulator, wherein said metal is in direct contact with at least one of said NFET or PFET gate insulators.

11. A method for producing a field effect transistor (FET), comprising:
depositing a metal layer by physical vapor deposition (PVD) in such manner that said metal layer is in a first state of stress; and
incorporating said metal layer into a gate of said FET in a manner that said metal layer imparts a second state of stress on a channel region of said FET, wherein said gate overlays said channel region, and said second state of stress is of opposite sign than said first state of stress.

12. The method of claim 11, wherein said transistor is selected to be N-type, wherein said first state of stress is selected to be compressive, wherein said second state of stress is tensile.

13. The method of claim 11, wherein said transistor is selected to be P-type, wherein said first state of stress is selected to be tensile, wherein said second state of stress is compressive.

14. The method of claim 11, wherein said metal layer is selected to be a Tungsten (W) layer.

15. The method of claim 11, wherein said PVD is selected to include sputtering.

16. The method of claim 11, wherein said incorporating of said metal layer into said gate is executed before a source and a drain of said FET have been activated.

17. The method of claim 11, wherein said incorporating of said metal layer into said gate is executed after a source and a drain of said FET have been activated.

18. A method for producing a device structure, comprising:
defining a first location for fabricating at least one NFET device and defining a second location for fabricating at least one PFET device;
depositing a first layer of a metal by physical vapor deposition (PVD) including over said first location, in such manner that said first layer of said metal is in a compressive state of stress;
depositing a second layer of said metal by PVD including over said second location, in such manner that said second layer of said metal is in a tensile state of stress; and
incorporating said first layer of said metal into a gate of said at least one NFET device, and incorporating said second layer of said metal into a gate of said at least one PFET device.

19. The method of claim 18, wherein said metal is selected be Tungsten (W).

20. The method of claim 18, wherein said PVD is selected to include sputtering.

21. The method of claim 18, wherein said incorporating of said first layer of said metal into said NFET gate and said incorporating of said second layer of said metal into said PFET gate is executed before sources and drains of said NFET and said PFET devices have been activated.

22. The method of claim 18, wherein said incorporating of said first layer of said metal into said NFET gate and said incorporating of said second layer of said metal into said PFET gate is executed after sources and drains of said NFET and said PFET devices have been activated.
